(19) United States
(12) Patent Application Publication
(10) Pub. No.: US 2020/0084881 A1
(43) Pub. Date: Mar. 12, 2020

(54) SEMICONDUCTOR MEMORY MODULE AND SEMICONDUCTOR MEMORY MODULE BOARD

(71) Applicant: Samsung Electronics Co., Ltd., Suwon-si (KR)

(72) Inventors: SIHYUNG LEE, Yongin-si (KR); CHANGWOO KO, Yeoju-si (KR); SEON-SIK KIM, Suwon-si (KR); JIYOON MOON, Incheon (KR); JINOH AHN, Gwacheon-si (KR)

(21) Appl. No.: 16/422,969

(22) Filed: May 25, 2019

(30) Foreign Application Priority Data
Sep. 10, 2018 (KR) 10-2018-0107857

(51) Int. Cl. H05K 1/02; H05K 1/18; H05K 1/11

(52) U.S. Cl. CPC H05K 1/0228; H05K 1/181; H05K 1/115; H05K 2201/10522; H05K 2201/10734; H05K 2201/09609; H05K 2201/10159

(57) ABSTRACT

A semiconductor memory module may include a printed circuit board and semiconductor memory packages provided on the printed circuit board. The printed circuit board may include a connector provided at a side region of the printed circuit board and configured to be connected to an external device, signal lines configured to connect the connector to the semiconductor memory packages, a first element configured to provide a first capacitive coupling between first signal lines, which are closest to each other, among the signal lines, a second element configured to provide a second capacitive coupling between second signal lines, which are disposed adjacent to each other with one signal line interposed therebetween, among the signal lines, and a third element configured to provide a third capacitive coupling between third signal lines, which are disposed adjacent to each other with two signal lines interposed therebetween, among the signal lines.

### CROSS-REFERENCE TO RELATED APPLICATIONS

This U.S. non-provisional patent application claims the benefit of priority under 35 U.S.C. § 119 to Korean Patent Application No. 10-2018-0107857, filed on Sep. 10, 2018, in the Korean Intellectual Property Office, the entire contents of which are hereby incorporated by reference.

### BACKGROUND

The present disclosure relates to a semiconductor device, and in particular, to a semiconductor memory module configured to prevent interference between signal lines and a semiconductor memory module board.

Electronic devices, such as computers and smart phones, are fabricated based on a printed circuit board. For example, the printed circuit board includes signal lines, which are connected to semiconductor packages and allow the electronic devices to perform their own functions.

The signal lines provided in the printed circuit board may suffer from interference, commonly referred to as crosstalk. The crosstalk can lead to deterioration in integrity of signals to be transmitted through the signal lines.

In the meantime, the electronic devices, such as computers and smart phones, may have various modules. For example, components of the electronic device may be fabricated as separate modules. The electronic device may be fabricated by assembling the separately fabricated modules.

The signal lines may be differently arranged in the separate modules. Thus, in two different modules, the strongest crosstalk to a specific signal line may be caused by different signal lines.

In existing studies to overcome the crosstalk issue, there has been no method to arrange signal lines differently for each module. As will be described below, the crosstalk issue may be overcome by differently arranging signal lines for each module.

### SUMMARY

Some embodiments provide a semiconductor memory module, which is configured to prevent crosstalk between signal lines, and a semiconductor memory module board.

According to certain exemplary embodiments, the disclosure is directed to a semiconductor memory module, comprising: a printed circuit board; and semiconductor memory packages provided on the printed circuit board, wherein the printed circuit board comprises: a connector provided at a side region of the printed circuit board and configured to be connected to an external device; signal lines configured to connect the connector and the semiconductor memory packages to each other; a first coupling element configured to provide a first capacitive coupling between first signal lines, which are closest to each other, among the signal lines; a second coupling element configured to provide a second capacitive coupling between second signal lines, which are disposed adjacent to each other with one signal line interposed therebetween, among the signal lines; and a third coupling element configured to provide a third capacitive coupling between third signal lines, which are disposed adjacent to each other with two signal lines interposed therebetween, among the signal lines.

According to certain exemplary embodiments, the disclosure is directed to a semiconductor memory module board, comprising: a connector configured to be connected to an external device; attachment regions configured to allow semiconductor memory packages to be attached thereto; signal lines configured to connect the connector and the attachment regions to each other; a first coupling element configured to provide a first capacitive coupling between a first signal line and a second signal line, which is closest to the first signal line, among the signal lines; a second coupling element configured to provide a second capacitive coupling between the first signal line and a third signal line, which is spaced adjacent to the first signal line with the second signal line interposed therebetween, among the signal lines; and a third coupling element configured to provide a third capacitive coupling between the first signal line and a fourth signal line, which is spaced adjacent to the first signal line with the second and third signal lines interposed therebetween, among the signal lines.

According to certain exemplary embodiments, the disclosure is directed to a semiconductor memory module board, comprising: a connector configured to be connected to an external device; attachment regions configured to allow semiconductor memory packages to be attached thereto; signal lines configured to connect the connector and the attachment regions to each other; a first coupling element configured to provide a first capacitive coupling between a first signal line and a second signal line, which is closest to the first signal line, among the signal lines; a second coupling element configured to provide a second capacitive coupling between the first signal line and a third signal line, which is spaced adjacent to the first signal line with the second signal line interposed therebetween, among the signal lines; and a third coupling element configured to provide a third capacitive coupling between the first signal line and a fourth signal line, which is spaced adjacent to the first signal line with the second and third signal lines interposed therebetween, among the signal lines.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a block diagram illustrating a computing device according to an example embodiment of the inventive concept.

FIG. 2 illustrates an example of signal lines, which are connected from a memory controller to a main memory.

FIG. 3 illustrates an example of a coupler according to an example embodiment of the inventive concept.

FIG. 4 illustrates an example of a coupler, which is configured to provide a capacitive coupling in units of a specific number of signal lines.

FIG. 5 is a block diagram illustrating a semiconductor memory module according to an example embodiment of the inventive concept.

FIG. 6 illustrates layers constituting a board according to an example embodiment of the inventive concept.

FIG. 7 illustrates an example of an attachment region, in which semiconductor memory packages on a printed circuit board are directly connected to signal lines connected to a second connector.

FIG. 8 is a sectional view taken along a line I-I′ of FIG. 7.

FIG. 9 is a sectional view taken along a line II-II′ of FIG. 7.

FIG. 10 is a sectional view taken along a line III-III′ of FIG. 7.

FIG. 11 is a sectional view taken along a line IV-IV′ of FIG. 7.

FIG. 12 illustrates an example of conductive patterns formed in a third layer, which is one of conductive layers.

FIG. 13 illustrates an example of conductive patterns formed in a fifth layer, which is one of conductive layers.

FIG. 14 illustrates an example of conductive patterns formed in a seventh layer, which is one of conductive layers.

FIG. 15 illustrates an example of conductive patterns formed in a ninth layer, which is one of conductive layers.

FIG. 16 illustrates an example of coupling patterns, which are extended from first to fourth signal patterns extended from first to fourth vias of FIG. 7.

FIG. 17 is a sectional view taken along a line V-V′ of FIG. 16.

FIG. 18 is a sectional view taken along a line VI-VI′ of FIG. 16.

FIG. 19 illustrates an example of signal patterns, which are connected to first to fourth signal patterns extended from first to third vias of FIG. 7.

FIG. 20 illustrates an example of coupling patterns forming a fourth layer and a third layer on the fourth layer.

FIG. 21 illustrates an example of coupling patterns forming a sixth layer and a fifth layer on the sixth layer.

FIG. 22 illustrates an example of coupling patterns forming an eighth layer and a seventh layer on the eighth layer.

FIG. 23 illustrates an example of coupling patterns forming a tenth layer and a ninth layer on the tenth layer.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

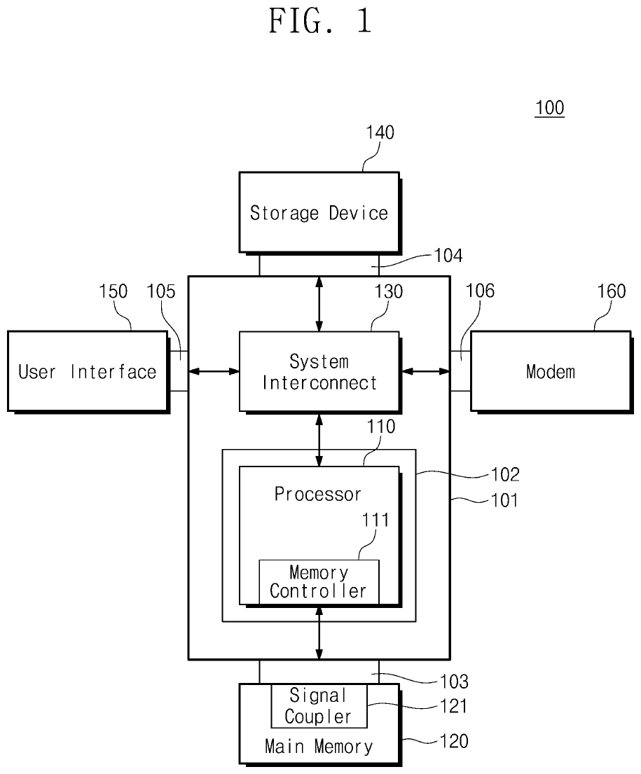

Example embodiments of the inventive concepts will now be described more fully with reference to the accompanying drawings, in which example embodiments are shown. FIG. 1 is a block diagram illustrating a computing device 100 according to some example embodiments of the inventive concept. Referring to FIG. 1, the computing device 100 may include a board 101, a processor 110, a main memory 120, a system interconnect 130, a storage device 140, a user interface 150, and a modem 160.

The board 101 may be a motherboard, on which the processor 110, the main memory 120, the system interconnect 130, the storage device 140, the user interface 150, and the modem 160 are mounted. The board 101 may include first to fifth connectors 102-106, on which the processor 110, the main memory 120, the storage device 140, the user interface 150, and the modem 160 are respectively mounted. The board 101 may be fabricated to include the system interconnect 130.

The processor 110 may include a central processing unit (CPU) or an application processor (AP), and the CPU or AP may control the computing device 100 and perform various operations. The processor 110 may include a memory controller 111, which is configured to control the main memory 120. The processor 110 may store in the main memory 120 codes or instructions required for operations and data associated with the operations.

The main memory 120 may be connected to the board 101 through the second connector 103. The main memory 120 may include a dynamic random access memory (DRAM). The main memory 120 may be a storage class memory (SCM) including a non-volatile memory (e.g., FLASH memory and phase change memory). The main memory 120 may be based on a dual in-line memory module (DIMM).

The main memory 120 may include a signal coupler 121. The signal coupler 121 may provide a capacitive coupling between signal lines for communication with the memory controller 111. In the signal coupler 121, the capacitive coupling may be used to prevent crosstalk between the signal lines.

The system interconnect 130 may provide channels between the processor 110, the storage device 140, the user interface 150, and the modem 160. The channels may be or may include, for example, physical media by which signals are transmitted and/or received, thereby facilitating communications between the processor 110, the storage device 140, the user interface 150, and the modem 160. The system interconnect 130 may be based on one of various protocols, such as Peripheral Component Interconnect express (PCIe), Nonvolatile Memory express (NVMe), Advanced eXtensible Interface (AXI), and ARM Microcontroller Bus Architecture (AMBA) protocols.

The storage device 140 may be connected to the board 101 through the third connector 104. The storage device 140 may serve as a secondary memory of the computing device 100. The storage device 140 may store source data of an operating system, application data and instructions, and user data, which will be processed by the processor 110. The storage device 140 may include at least one of a hard disk drive (HDD), a solid state drive (SSD), or an optical disk drive (ODD).

The user interface 150 may be connected to the board 101 through the fourth connector 105. The user interface 150 may be configured to exchange information with a user. The user interface 150 may include a user input interface (e.g., a keyboard, a mouse, a touch panel, a motion sensor, a microphone, and so forth), which is used to receive information from a user. The user interface 150 may further include a user output interface (e.g., a display device, a speaker, a beam projector, a printer, and so forth), which is used to provide information to a user.

The modem 160 may be connected to the board 101 through the fifth connector 106. The modem 160 may be configured to exchange data with an external device in a wireless or wired manner. In some embodiments, the modem 160 may be integrated in the board 101 or the processor 110.

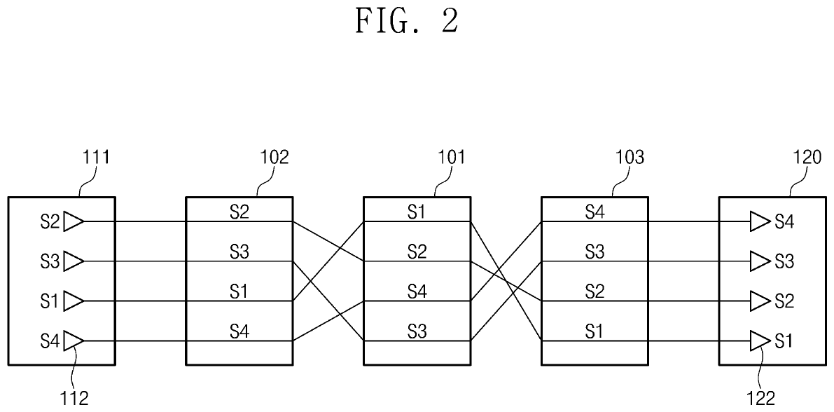

FIG. 2 illustrates an example of signal lines, which are connected from the memory controller 111 to the main memory 120. Referring to FIGS. 1 and 2, transmitters 112 of the memory controller 111 may be connected to receivers 122 of the main memory 120 through the first connector 102, the board 101, and the second connector 103. Similarly, receivers of the memory controller 111 may also be connected to transmitters of the main memory 120 through the first connector 102, the board 101, and the second connector 103.

In some embodiments, an active device may not be provided between the memory controller 111 and the main memory 120. For example, signal lines between the memory controller 111 and the main memory 120 may be composed of only passive devices. Passive devices may include, for example, wires, pads, internal electrical lines, through vias, etc.

The main memory 120 may receive first to fourth signals S1-S4 from the second connector 103. In most cases, a crosstalk issue in a specific signal line may be caused by a signal line closest to the specific signal line. For example, the signals lines that are in closest proximity may cause cross-talk with one another. The arrangement or disposition of the signal lines of the first to fourth signals S1-S4 may be changed while passing through the first connector 102, the board 101, and the second connector 103.

For example, in the second connector 103 or the main memory 120, the signal line of the second signal S2 may be closest to the signal line of the first signal S1. The signal lines of the first signal S1 and the third signal S3 may be closest to the signal lines of the second signal S2. The signal lines of the second signal S2 and the fourth signal S4 may be closest to the signal line of the third signal S3. The signal line of the third signal S3 may be closest to the signal line of the fourth signal S4.

In the board 101, the signal line of the fourth signal S4 may be closest to the signal line of the third signal S3. The signal lines of the third signal S3 and the second signal S2 may be closest to the signal line of the fourth signal S4. The signal lines of the fourth signal S4 and the first signal S1 may be closest to the signal line of the second signal S2. The signal line of the second signal S2 may be closest to the signal line of the first signal S1.

In the memory controller 111 or the first connector 102, the signal line of the first signal S1 may be closest to the signal line of the fourth signal S4. The signal lines of the fourth signal S4 and the third signal S3 may be closest to the signal line of the first signal S1. The signal lines of the first signal S1 and the second signal S2 may be closest to the signal line of the third signal S3. The signal line of the third signal S3 may be closest to the signal line of the second signal S2.

That is, if the arrangement or disposition of the signal lines varies on a routing path of the specific signal line, a cause resulting in the crosstalk issue in the specific signal line may be changed depending on a position on the routing path of the specific signal line. This means that the crosstalk issue between the signal lines may not be effectively prevented, even when the main memory 120 is configured to provide a capacitive coupling between each nearest pair of the signal lines therein.

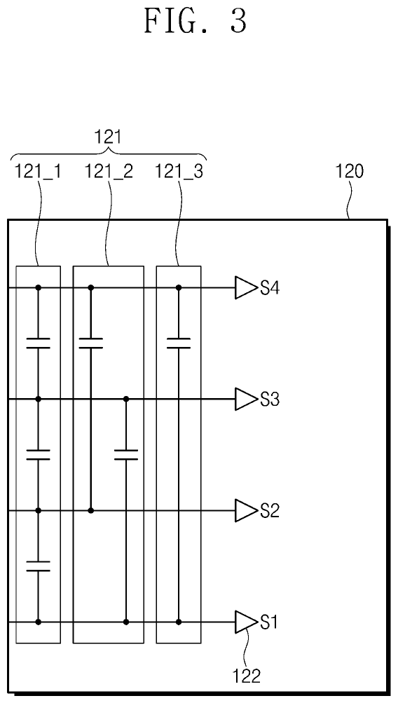

FIG. 3 illustrates an example of the signal coupler 121 according to an example embodiment of the inventive concept. Referring to FIGS. 1 and 3, the signal coupler 121 may include a first coupling element 121_1, a second coupling element 121_2, and a third coupling element 121_3.

The first coupling element 121_1 may include capacitors, each of which provides a capacitive coupling between each nearest pair of the signal lines in the main memory 120. The second coupling element 121_2 may include capacitors, each of which provides a capacitive coupling between each pair of signal lines, which are adjacent to each other with one signal line interposed therebetween. The third coupling element 121_3 may include capacitor(s), which provides a capacitive coupling between each pair of signal lines, which are adjacent to each other with two signal lines interposed therebetween.

According to some example embodiments of the inventive concept, as described above, a capacitive coupling may be provided between each nearest pair of the signal lines as well as between each pair of signal lines, which are adjacent to each other with a specific number of signal line(s) interposed between. For example, the first, second, and third coupling elements 121_1, 121_2, and 121_3 may provide capacitive coupling between pairs of signal lines, where the pairs of signal lines are identified according to their physical configuration within the main memory 120. Thus, even when the arrangement or disposition of the signal lines is changed outside the main memory 120, it may be possible to prevent the crosstalk from occurring between the signal lines.

In particular, in the case where, as described with reference to FIG. 2, the signal lines between the memory controller 111 and the main memory 120 are composed of passive devices, the signal coupler 121 of the main memory 120 may prevent the crosstalk from occurring between all of the signal lines between the memory controller 111 and the main memory 120.

So far, the signal coupler 121 having four signal lines has been described as an example embodiment of the inventive concept. However, the inventive concept is not limited to the example of the signal coupler 121 with four signal lines.

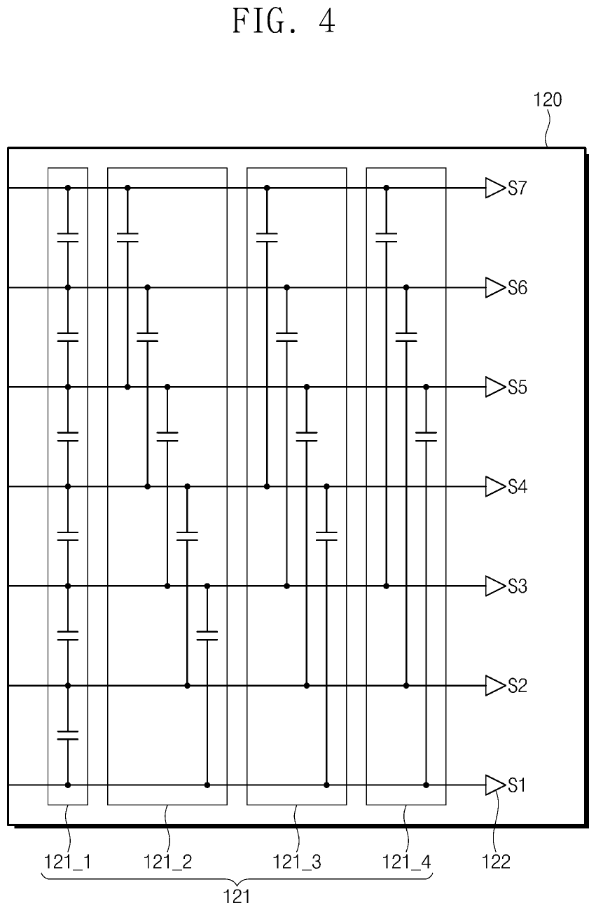

FIG. 4 illustrates an example of the signal coupler 121, which provides a capacitive coupling in units of a specific number of signal lines. Referring to FIGS. 1 and 4, the signal coupler 121 may include a first coupling element 121_1, a second coupling element 121_2, a third coupling element 121_3, and a fourth coupling element 121_4, which are associated with signal lines of the first to seventh signals S1-S7.

As described with reference to FIG. 3, the first coupling element 121_1 may provide a capacitive coupling between each nearest pair of the signal lines. The second coupling element 121_2 may provide a capacitive coupling between each pair of signal lines, which are adjacent to each other with one signal line interposed therebetween. The third coupling element 121_3 may provide a capacitive coupling between each pair of signal lines, which are adjacent to each other with two signal lines interposed therebetween.

Compared with FIG. 3, the signal coupler 121 may further include the fourth coupling element 121_4. The fourth coupling element 121_4 may include capacitors, each of which provides a capacitive coupling between each pair of signal lines, which are adjacent to each other with three signal lines interposed therebetween.

For example, each nearest pair of the signal lines may have proximity of first order. The signal lines, which are adjacent to each other with one signal line interposed therebetween, may have proximity of second order. The signal lines, which are adjacent to each other with two signal lines interposed therebetween, may have proximity of third order. The signal lines, which are adjacent to each other with three signal lines interposed therebetween, may have proximity of fourth order.

To avoid an excessive increase in complexity and cost of the main memory 120, the order of proximity of signal lines, to which the signal coupler 121 provides the capacitive coupling, may be limited. For example, in the structure of FIG. 4, the signal coupler 121 may provide the capacitive coupling to signal lines having the proximity of fourth order, but not to signal lines having the proximity of fifth or higher order.

In the case where the signal coupler 121 provides the capacitive coupling to signal lines having the proximity of i-th order (here, i is a positive integer), i signal lines, which are adjacent to each other, may be capacitively coupled to each other completely. For example, the signal coupler 121 may be configured to provide a complete or multi-order capacitive coupling in units of i signal lines. When the main memory 120 exchanges information with the memory controller 111 through n signal lines, the signal coupler 121 provides a multi-order capacitive coupling of all signal lines of the set of signal lines between a k-th signal line to a (k+i)-th signal line, where k is a positive integer smaller than n. For example, the k may be an integer which varies in a range from 1 to n−i.

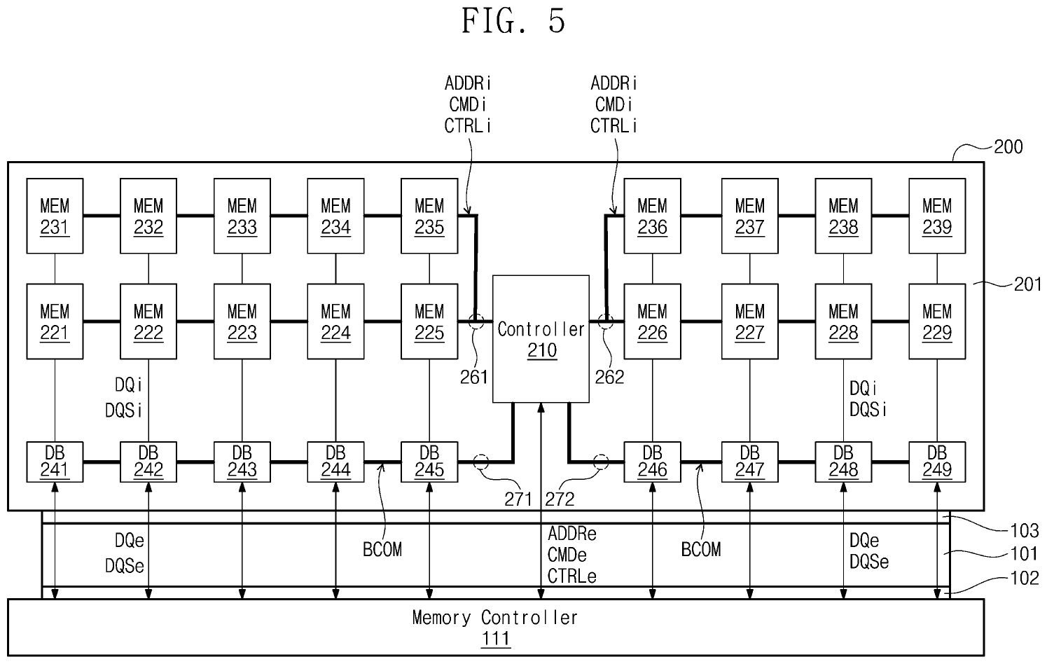

FIG. 5 is a block diagram illustrating a semiconductor memory module 200 according to some example embodiments of the inventive concept. For example, the semiconductor memory module 200 may be used as the main memory 120. Referring to FIGS. 1 and 5, the semiconductor memory module 200 may include a controller 210, first memory devices (MEM) 221-229, second memory devices (MEM) 231-239, and data buffers 241-249.

The controller 210, the first memory devices 221-229, the second memory devices 231-239, and the data buffers 241-249 may be implemented with different semiconductor memory packages, and each of the semiconductor memory packages may be disposed on a printed circuit board 201. For example, the first memory devices 221-229 may be disposed on a top surface of the printed circuit board 201, and the second memory devices 231-239 may be disposed on a bottom surface of the printed circuit board 201.

Each of the first memory devices 221-229 and the second memory devices 231-239 may include one of various memories (e.g., a dynamic random access memory (DRAM), a phase change random access memory (PRAM), a FLASH memory, and so forth).

The controller 210 may receive an external address ADDRe, an external command CMDe, and external control signals CTRLe from the memory controller 111, which is located outside the controller 210, through the first connector 102, the board 101, and the second connector 103. The external address ADDRe may be received in the form of a set of address signals, and the external command CMDe may be received in the form of a set of command signals.

The controller 210 may transfer the external address ADDRe, the external command CMDe, and the external control signals CTRLe, which are used as or converted to an internal address ADDRi, an internal command CMDi, and internal control signals CTRLi, respectively, to the first memory devices 221-229 and the second memory devices 231-239 through first control signal lines 261 and 262.

The controller 210 may control the first memory devices 221-229 and the second memory devices 231-239 using the internal address ADDRi, the internal command CMDi, and the internal control signals CTRLi.

The controller 210 may transfer a buffer command BCOM to the data buffers 241-249 through second control signal lines 271 and 272, in response to the external command CMDe and the external control signals CTRLe. The controller 210 may control the data buffers 241-249 using the buffer command BCOM. The controller 210 may include a register clock driver (RCD).

The first memory devices 221-229 and the second memory devices 231-239 may be connected to the data buffers 241-249, respectively. The first memory devices 221-229 and the second memory devices 231-239 may exchange internal data signals DQi and internal data strobe signals DQSi with the data buffers 241-249.

The data buffers 241-249 may exchange external data signals DQe and external data strobe signals DQSe with the memory controller 111 through the first connector 102, the board 101, and the second connector 103.

The semiconductor memory module 200 may exchange the external address ADDRe, the external command CMDe, the external control signals CTRLe, the external data signals DQe, and the external data strobe signals DQSe with the memory controller 111 through the first connector 102, the board 101, and the second connector 103.

The printed circuit board 201 of the semiconductor memory module 200 may be configured to provide a multi-order capacitive coupling to signal lines, which are used to transfer the external address ADDRe, the external command CMDe, the external control signals CTRLe, the external data signals DQe, and the external data strobe signals DQSe, and to prevent the crosstalk from occurring between the signal lines.

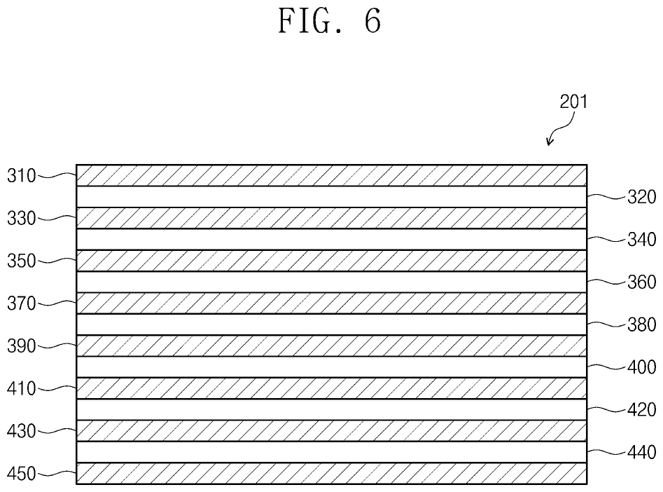

FIG. 6 illustrates layers of the printed circuit board 201 according to some example embodiments of the inventive concept. Referring to FIGS. 1 and 6, the printed circuit board 201 may include first to fifteenth layers 310-450. Each of the layers 310, 330, 350, 370, 390, 410, 430, and 450 depicted with a hatched pattern may be a layer or a conductive layer, in which conductive patterns (e.g., thin copper patterns) are provided. The conductive patterns may form the signal lines and the signal coupler 121. Each of the layers 320, 340, 360, 380, 400, 420, and 440 depicted with an unhatched pattern may be a layer (e.g., an insulating layer), which is formed of or includes an insulating material, and on which the conductive patterns (e.g., thin copper patterns) are disposed or attached thereon or therebelow.

An extent of signal lines and relationship of proximity of the signal lines may be defined in at least one conductive layer of the conductive the layers 310, 330, 350, 370, 390, 410, 430, and 450. For example, the extent and relationship of proximity of the signal lines may be defined in one of the conductive the layers 310, 330, 350, 370, 390, 410, 430, and 450, in which all of the signal lines are disposed.

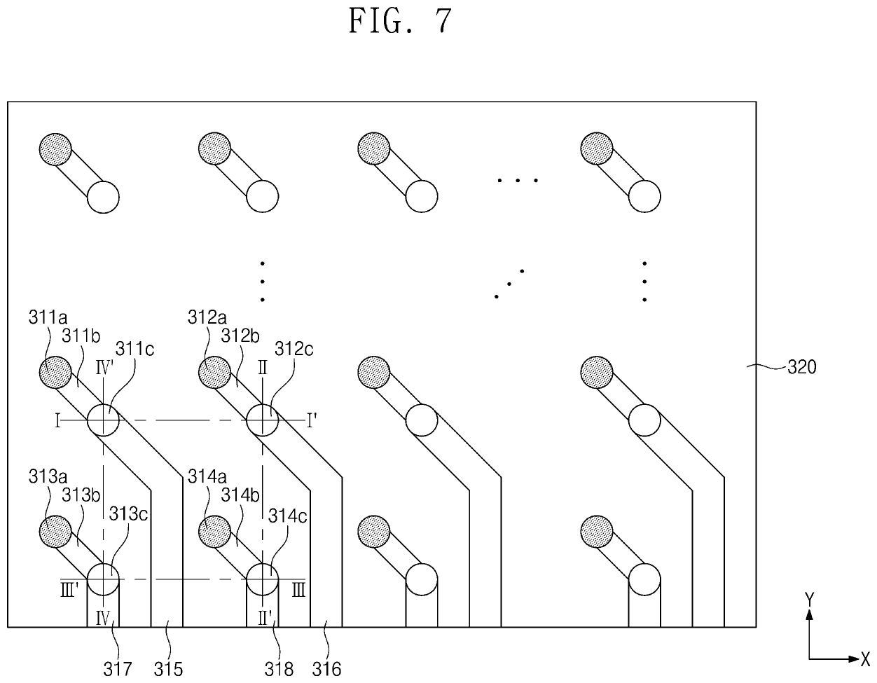

FIG. 7 illustrates an example of an attachment region, in which semiconductor memory packages on the printed circuit board 201 are directly connected to signal lines connected to the second connector 103. For example, in the semiconductor memory module 200 described with reference to FIG. 5, the attachment region may be provided for the controller 210 and the data buffers 241-249.

The semiconductor memory module 200 shown in FIG. 5 may be a module that is based on a Load Reduced Dual In-Line Memory Module (LRDIMM). In the case where the semiconductor memory module 200 is based on a Registered DIMM (RDIMM), the data buffers 241-249 may be removed from the semiconductor memory module 200. The external data signals DQe and the external data strobe signals DQSe may be directly provided to the first memory devices 221-229 and the second memory devices 231-239. In the RDIMM-based module, the attachment region may be provided for the controller 210, the first memory devices 221-229, and the second memory devices 231-239.

In the case where the semiconductor memory module 200 is based on the DIMM, the data buffers 241-249 and the controller 210 may be removed from the semiconductor memory module 200. The external address ADDRe, the external command CMDe, and the external control signals CTRLe may be directly provided to the first memory devices 221-229 and the second memory devices 231-239. In the DIMM-based module, the attachment region may be provided for the first memory devices 221-229 and the second memory devices 231-239.

Referring to FIGS. 5 to 7, an attachment region in the second layer 320 may include conductive patterns disposed on the second layer 320, which is one of the insulating layers of the printed circuit board 201. The conductive patterns may form the first layer 310, which one of the conductive layers of the printed circuit board 201.

The conductive patterns may include attachment patterns, to which solder balls of the semiconductor memory package are attached. In FIG. 7, the attachment patterns are depicted with dotted patterns. The attachment patterns may be arranged in a first direction X and a second direction Y to form a matrix-shaped arrangement. For convenience in description, the signal coupler 121 will be described with reference to some of the attachment patterns (e.g., first to fourth attachment patterns 311a-314a).

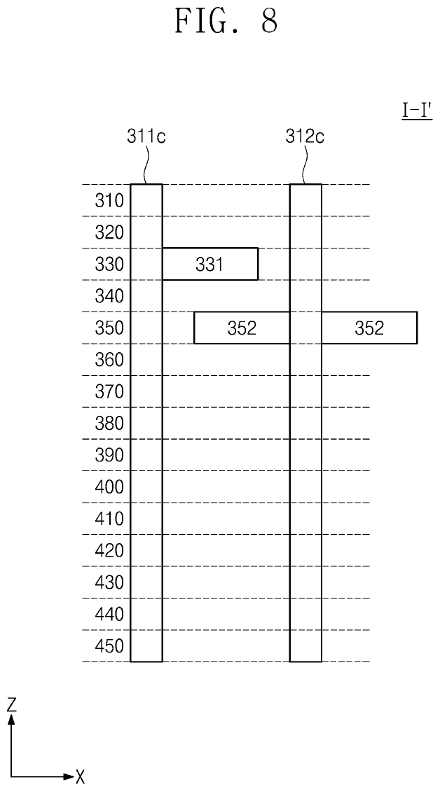

The first to fourth attachment patterns 311a-314a may be respectively connected to first to fourth vias 311c-314c through first to fourth intermediate patterns 311b-314b. The first to fourth vias 311c-314c may be arranged in the first direction X and the second direction Y to form a matrix-shaped arrangement. The matrix-shaped arrangement of the first to fourth vias 311c-314c may correspond to the matrix-shaped arrangement of the first to fourth attachment patterns 311a-314a. The first to fourth vias 311c-314c may penetrate the first to fifteenth layers 310-450 of the printed circuit board 201 in a direction perpendicular to the top or bottom surface of the printed circuit board 201 (e.g., see FIGS. 8 to 11).

The first to fourth vias 311c-314c may be connected to first to fourth signal patterns 315-318, respectively. The first to fourth signal patterns 315-318 may be routed in the first to fifteenth layers 310-450 of the printed circuit board 201 or some of them may be connected to the second connector 103.

FIG. 8 is a sectional view taken along a line I-I′ of FIG. 7. Referring to FIGS. 7 and 8, in the third layer 330, which is one of the conductive layers, a first coupling pattern 331 may extend from the first via 311c. In the fifth layer 350, which is one of the conductive layers, a second coupling pattern 352 may extend from the second via 312c. The first and second coupling patterns 331 and 352 (as well as the other coupling patterns described herein) may each be an electrical stub formed as wiring and/or plate that is connected at only one end. Thus, the coupling patterns may not be connected to transmit a direct current along their lengths. In some examples described herein, length directions of the coupling pattern may extend away from length directions of the signal pattern length direction (at the point of their connection to the signal pattern) (e.g., in a perpendicular direction to the signal pattern length direction). FIG. 8 shows an example of this, with coupling pattern 331 extending away from signal pattern 311c and coupling pattern 352 extending away from signal pattern 312c. It will be appreciated that coupling patterns may have one end terminating at a signal pattern or may be connected to a signal pattern at some location between their ends. In addition, each of the first and second coupling patterns 331 and 352 (as well as the other coupling patterns described herein) may form one electrode of a corresponding capacitor, such as those described elsewhere herein. As shown in FIG. 8, a capacitor is formed with first and second coupling patterns 331 and 352 as capacitor electrodes with a capacitor dielectric formed by the portion of fourth insulating layer 340 interposed therebetween. The coupling patterns (as well as the other coupling patterns described herein) may extend in the same direction and have at least some of one of their major surfaces (here the upper surface of coupling pattern 352 and the lower surface of coupling pattern 331) face each other. In some examples, a major surface of coupling pattern may be a surface of the coupling pattern with having a surface area equal to or greater than all other surface areas of other surfaces of the coupling pattern.

The first coupling pattern 331 and the second coupling pattern 352 may be overlapped with each other in a direction perpendicular to the top or bottom surface of the printed circuit board 201 (e.g., third direction Z). The first coupling pattern 331 and the second coupling pattern 352 may be capacitively coupled with each other. In other words, the first coupling pattern 331 and the second coupling pattern 352 may form a capacitor providing a capacitive coupling between the first and second signal patterns 315 and 316, which are disposed adjacent to each other with the fourth signal pattern 318 interposed therebetween.

Additionally, a portion of the second coupling pattern 352 extended in a right direction of the first direction X of FIG. 8 may be capacitively coupled with another neighboring via (e.g., the via located next to the second via 312c opposite to the first via 311c in the first direction X of FIG. 7), not with the first to fourth vias 311c-314c. Thus, as described with reference to FIG. 4, it may be possible to provide a complete or multi-order capacitive coupling to each group consisting of a specific number of signal lines.

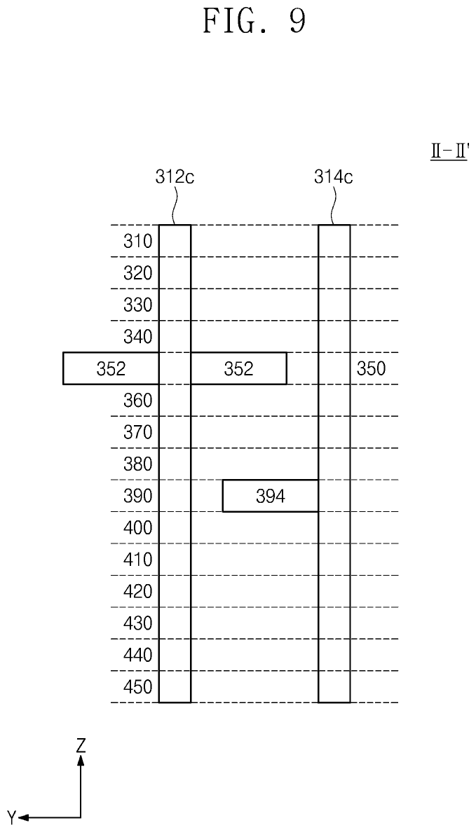

FIG. 9 is a sectional view taken along a line II-II′ of FIG. 7. Referring to FIGS. 7 and 9, in the fifth layer 350, which is one of the conductive layers, the second coupling pattern 352 may extend from the second via 312c. In the ninth layer 390, which is one of the conductive layers, a fourth coupling pattern 394 may extend from the fourth via 314c.

The second coupling pattern 352 and the fourth coupling pattern 394 may be partially overlapped with each other in a direction perpendicular to the top or bottom surface of the printed circuit board 201 (e.g., third direction Z). The second coupling pattern 352 and the fourth coupling pattern 394 may be capacitively coupled with each other. In other words, the second coupling pattern 352 and the fourth coupling pattern 394 may form a capacitor providing a capacitive coupling between the second and fourth signal patterns 316 and 318, which are located closest to each other.

Additionally, a portion of the second coupling pattern 352 extended in a left direction of the second direction Y of FIG. 8 may be capacitively coupled with another neighboring via (e.g., the via located next to the second via 312c opposite to the fourth via 314c in the second direction Y of FIG. 7), not with the first to fourth vias 311c-314c. Thus, as described with reference to FIG. 4, it may be possible to provide a complete or multi-order capacitive coupling to each group consisting of a specific number of signal lines.

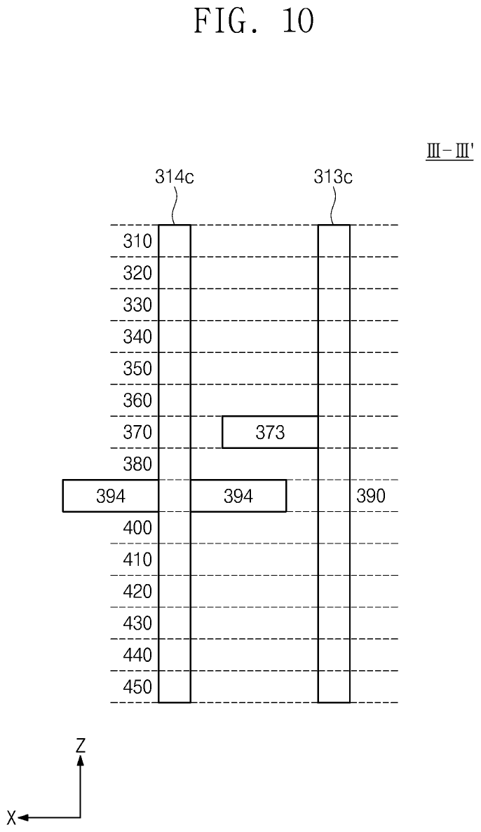

FIG. 10 is a sectional view taken along a line III-III′ of FIG. 7. Referring to FIGS. 7 and 10, in the seventh layer 370, which is one of the conductive layers, a third coupling pattern 373 may extend from the third via 313c. In the ninth layer 390, which is one of the conductive layers, the fourth coupling pattern 394 may extend from the fourth via 314c.

The third coupling pattern 373 and the fourth coupling pattern 394 may be partially overlapped with each other in a direction perpendicular to the top or bottom surface of the printed circuit board 201 (e.g., third direction Z). The third coupling pattern 373 and the fourth coupling pattern 394 may be capacitively coupled with each other. In other words, the third coupling pattern 373 and the fourth coupling pattern 394 may form a capacitor providing a capacitive coupling between the third and fourth signal patterns 317 and 318, which are disposed adjacent to each other with the first signal pattern 315 interposed therebetween.

Additionally, a portion of the fourth coupling pattern 394 extended in a left direction of the first direction X of FIG. 10 may be capacitively coupled with a neighboring other via (e.g., the via located next to the second via 312c opposite to the third via 313c in the first direction X of FIG. 7), not with the first to fourth vias 311c-314c. Thus, as described with reference to FIG. 4, it may be possible to provide a complete or multi-order capacitive coupling to each group consisting of a specific number of signal lines.

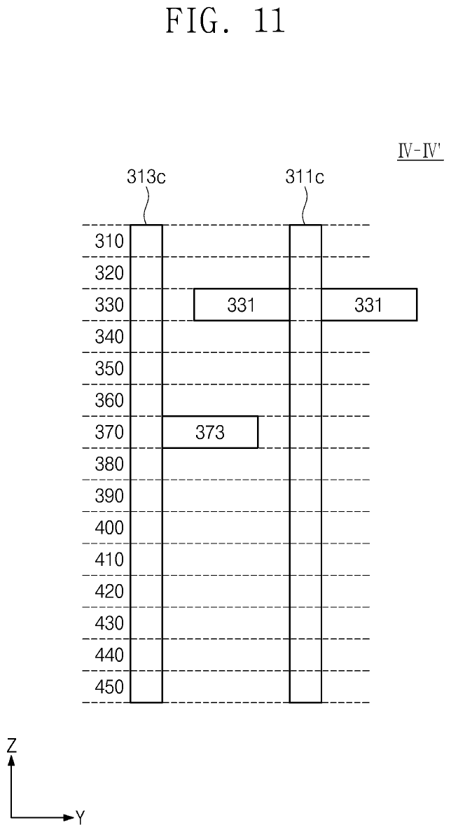

FIG. 11 is a sectional view taken along line IV-IV′ of FIG. 7. Referring to FIGS. 7 and 11, in the third layer 330, which is one of the conductive layers, the first coupling pattern 331 may extend from the first via 311c. In the seventh layer 370, which is one of the conductive layers, the third coupling pattern 373 may extend from the third via 313c.

The first coupling pattern 331 and the third coupling pattern 373 may be partially overlapped with each other in a direction perpendicular to the top or bottom surface of the printed circuit board 201 (e.g., third direction Z). The first coupling pattern 331 and the third coupling pattern 373 may be capacitively coupled with each other. In other words, the first coupling pattern 331 and the third coupling pattern 373 may form a capacitor providing a capacitive coupling between the first and third signal patterns 315 and 317, which are located closest to each other.

Additionally, a portion of the first coupling pattern 331 extended in a right direction of the second direction Y of FIG. 11 may be capacitively coupled with a neighboring other via (e.g., the via located next to the first via 311c opposite to the third via 313c in the second direction Y of FIG. 7), not with the first to fourth vias 311c-314c. Thus, as described with reference to FIG. 4, it may be possible to provide a complete or multi-order capacitive coupling to each group consisting of a specific number of signal lines.

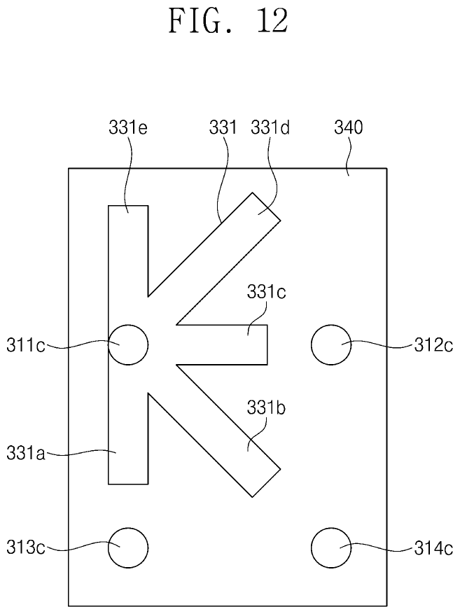

FIG. 12 illustrates an example of conductive patterns formed in the third layer 330, which is one of the conductive layers. The conductive patterns of the third layer 330 may be formed on the fourth layer 340, which is one of the insulating layers. Referring to FIG. 12, the first coupling pattern 331 may extend from the first via 311c. The first coupling pattern 331 may include first to fifth portions 331a-331e, which are respectively extended in five different directions.

The first to third portions 331a-331c may be capacitively coupled with the second to fourth coupling patterns 352, 373, and 394 of the second to fourth vias 312c-314c. For example, the first portion 331a may be capacitively coupled with the third coupling pattern 373 of the third via 313c, the second portion 331b may be capacitively coupled with the fourth coupling pattern 394 of the fourth via 314c, and the third portion 331c may be capacitively coupled with the second coupling pattern 352 of the second via 312c. The fourth and fifth portions 331d and 331e may be capacitively coupled with coupling pattern(s) of other via(s) (not illustrated in FIG. 12), not with the second to fourth vias 312c-314c.

In some embodiments, similar to that shown in FIG. 3, the first to fourth vias 311c-314c may be capacitively coupled with each other, but not with other external vias. In such embodiments, the fourth and fifth portions 331d and 331e may be removed.

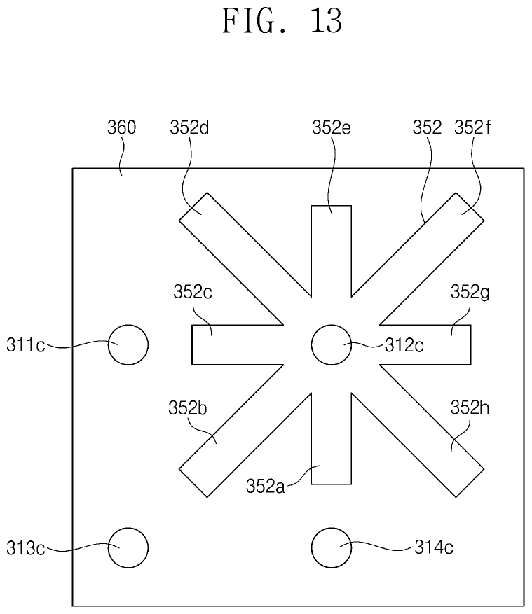

FIG. 13 illustrates an example of conductive patterns formed in the fifth layer 350, which is one of the conductive layers. The conductive patterns of the fifth layer 350 may be formed on the sixth layer 360, which is one of the insulating layers. Referring to FIG. 13, the second coupling pattern 352 may extend from the second via 312c. The second coupling pattern 352 may include first to eighth portions 352a-352h, which are respectively extended in eight different directions.

The first to third portions 352a-352c may be capacitively coupled with the first, third, and fourth coupling patterns 331, 373, and 394 of the first, third, and fourth vias 311c, 313c, and 314c. For example, the first portion 352a may be capacitively coupled with the fourth coupling pattern 394 of the fourth via 314c, the second portion 352b may be capacitively coupled with the third coupling pattern 373 of the third via 313c, and the third portion 352c may be capacitively coupled with the first coupling pattern 331 of the first via 311c. The fourth to eighth portions 352d-352h may be capacitively coupled with coupling pattern(s) of other via(s), not with the first, third, and fourth vias 311c, 313c, and 314c.

In some embodiments, similar to that shown in FIG. 3, the first to fourth vias 311c-314c may be capacitively coupled with each other, but not with other external vias. In such embodiments, the fourth to eighth portions 352d-352h may be removed.

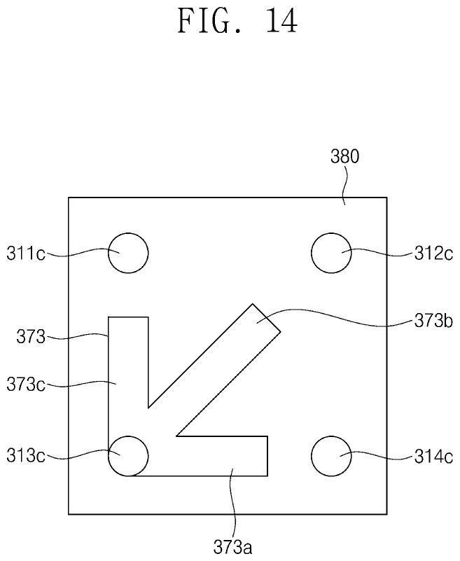

FIG. 14 illustrates an example of conductive patterns formed in the seventh layer 370, which is one of the conductive layers. The conductive patterns of the seventh layer 370 may be formed on the eighth layer 380, which is one of the insulating layers. Referring to FIG. 14, the third coupling pattern 373 may extend from the third via 313c. The third coupling pattern 373 may include first to third portions 373a-373c, which are respectively extended in three different directions.

The first to third portions 373a-373c may be capacitively coupled with the first, second, and fourth coupling patterns 351, 352, and 394 of the first, second, and fourth vias 311c, 312c, and 314c. For example, the first portion 373a may be capacitively coupled with the fourth coupling pattern 394 of the fourth via 314c, the second portion 373b may be capacitively coupled with the second coupling pattern 352 of the second via 312c, and the third portion 373c may be capacitively coupled with the first coupling pattern 331 of the first via 311c.

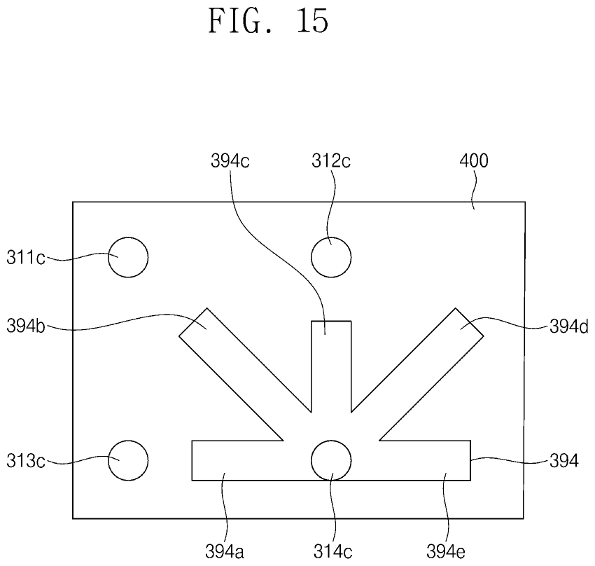

FIG. 15 illustrates an example of conductive patterns formed in the ninth layer 390, which is one of the conductive layers. The conductive patterns of the ninth layer 390 may be formed on the tenth layer 400, which is one of the insulating layers. Referring to FIG. 15, the fourth coupling pattern 394 may extend from the fourth via 314c. The fourth coupling pattern 394 may include first to fifth portions 394a-394e, which are respectively extended in five different directions.

The first to third portions 394a-394c may be capacitively coupled with the first to third coupling patterns 331, 352, and 373 of the first to third vias 311c-313c. For example, the first portion 394a may be capacitively coupled with the third coupling pattern 373 of the third via 313c, the second portion 394b may be capacitively coupled with the first coupling pattern 331 of the first via 311c, and the third portion 394c may be capacitively coupled with the second coupling pattern 352 of the second via 312c. The fourth and fifth portions 394d and 394e may be capacitively coupled with a coupling pattern(s) of other via(s), not with the first to third vias 311c-313c.

In some embodiments, similar to that shown in FIG. 3, the first to fourth vias 311c-314c may be capacitively coupled with each other, but not with other external vias. In such embodiments, the fourth and fifth portions 394d and 394e may be removed.

Referring to FIGS. 7 and 12 to 15, the first portion 331a of the first coupling pattern 331 and the third portion 373c of the third coupling pattern 373 may be capacitively coupled with each other and may correspond to the first coupling element 121_1 (e.g., see FIG. 3) providing a capacitive coupling between the first and third signal patterns 315 and 317 closest to each other.

The second portion 331b of the first coupling pattern 331 and the second portion 394b of the fourth coupling pattern 394 may be capacitively coupled with each other and may correspond to the first coupling element 121_1 (e.g., see FIG. 3) providing a capacitive coupling between the first and fourth signal patterns 315 and 318 closest to each other.

The third portion 331c of the first coupling pattern 331 and the third portion 352c of the second coupling pattern 352 may be capacitively coupled with each other and may correspond to the second coupling element 121_2 providing a capacitive coupling between the first and second signal patterns 315 and 316, which are disposed adjacent to each other with the fourth signal pattern 318 interposed therebetween.

The first portion 352a of the second coupling pattern 352 and the third portion 394c of the fourth coupling pattern 394 may be capacitively coupled with each other and may correspond to the first coupling element 121_1 providing a capacitive coupling between the second and fourth signal patterns 316 and 318, which are located closest to each other.

The second portion 352b of the second coupling pattern 352 and the second portion 373b of the third coupling pattern 373 may be capacitively coupled with each of and may correspond to the third coupling element 121_3 providing a capacitive coupling between the second and third signal patterns 316 and 317, which are disposed adjacent to each other with the first and fourth signal patterns 315 and 318 interposed therebetween. The third portion 352c of the second coupling pattern 352 and the third portion 331c of the first coupling pattern 331 may be capacitively coupled with each other and may correspond to the second coupling element 121_2 providing a capacitive coupling between the first and second signal patterns 315 and 316, which are disposed adjacent to each other with the fourth signal pattern 318 interposed therebetween.

The first portion 373a of the third coupling pattern 373 and the first portion 394a of the fourth coupling pattern 394 may be capacitively coupled with each other and may correspond to the second coupling element 121_2 providing a capacitive coupling between the third and fourth signal patterns 317 and 318, which are disposed adjacent to each other with the first signal pattern 315 interposed therebetween.

The second portion 373b of the third coupling pattern 373 and the second portion 352b of the second coupling pattern 352 may be capacitively coupled with each other and may correspond to the third coupling element 121_3 providing a capacitive coupling between the second and third signal patterns 316 and 317, which are disposed adjacent to each other with the first and fourth signal patterns 315 and 318 interposed therebetween. The third portion 373c of the third coupling pattern 373 and the first portion 331a of the first coupling pattern 331 may be capacitively coupled with each other and may correspond to the first coupling element 121_1 providing a capacitive coupling between the first and third signal patterns 315 and 317, which are located closest to each other.

The first portion 394a of the fourth coupling pattern 394 and the first portion 373a of the third coupling pattern 373 may be capacitively coupled with each other and may correspond to the second coupling element 121_2 providing a capacitive coupling between the third and fourth signal patterns 317 and 318, which are disposed adjacent to each other with the first signal pattern 315 interposed therebetween.

The second portion 394b of the fourth coupling pattern 394 and the second portion 331b of the first coupling pattern 331 may be capacitively coupled with each other and may correspond to the first coupling element 121_1 providing a capacitive coupling between the first and fourth signal patterns 315 and 318, which are located closest to each other. The third portion 394c of the fourth coupling pattern 394 and the first portion 352a of the second coupling pattern 352 may be capacitively coupled with each other and may correspond to the first coupling element 121_1 providing a capacitive coupling between the second and fourth signal patterns 316 and 318, which are located closest to each other.

As described above, due to the first to fourth coupling patterns 331, 352, 373, and 394 of the first to fourth vias 311c-314c, the first to fourth signal patterns 315-318 may be capacitively coupled with each other in a complete multi-order coupling manner. In other words, the complete multi-order capacitive coupling may be provided up to signal patterns having the proximity of third order.

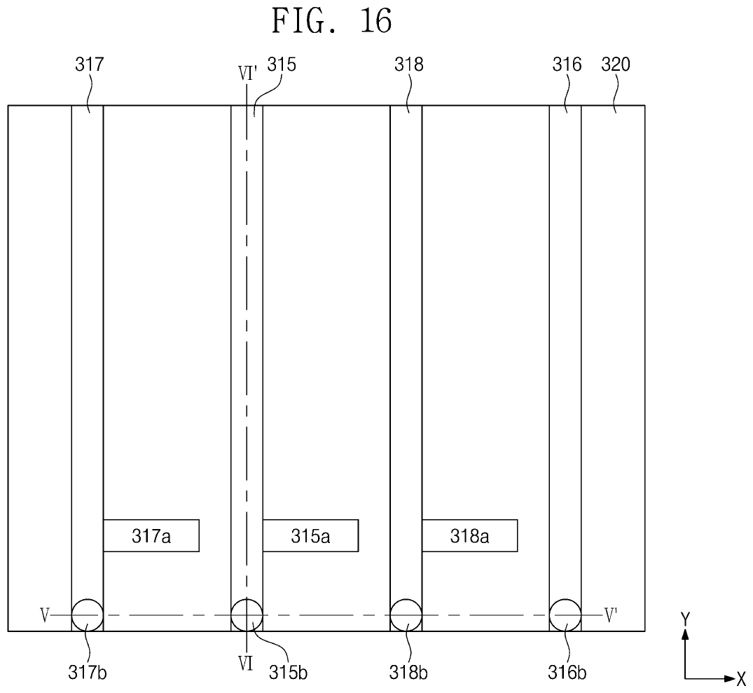

FIG. 16 illustrates an example of coupling patterns, which are extended from the first to fourth signal patterns 315-318 extended from the first to fourth vias 311c-314c of FIG. 7. For example, the first to fourth signal patterns 315-318 may extend from the first to fourth vias 311c-314c of FIG. 7 to first to fourth connection vias 315b-318b, respectively, in an opposite direction of the second direction Y. For example, the first signal pattern 315 may extend from the first via 311c to the first connection via 315b, the second signal pattern 316 may extend from the second via 312c to the second connection via 316b, the third signal pattern 317 may extend from the third via 313c to the third connection via 317b, and the fourth signal pattern 318 may extend from the fourth via 314c to the fourth connection via 318b.

The first to fourth connection vias 315b-318b may penetrate the printed circuit board 201 and may be electrically connected to the first to fourth signal patterns 315-318, respectively, similar to the first to fourth vias 311c-314c. For example, the first to fourth signal patterns 315-318 may be disposed on the second layer 320 to form patterns of the first layer 310. As used herein, items described as being “electrically connected” are configured such that an electrical signal can be passed from one item to the other.

The signal patterns of the first layer 310 may further include first coupling patterns 315a, 317a, and 318a, which are respectively extended from the first, third, and fourth signal patterns 315, 317, and 318. The first coupling patterns 315a, 317a, and 318a may be respectively extended from the first, third, and fourth signal patterns 315, 317, and 318 of the first layer 310 in the first direction X.

In the layers located below the first layer 310 and the second layer 320, various coupling patterns may be provided to form the signal coupler 121, along with the first coupling patterns 315a, 317a, and 318a. In the layers located below the first layer 310 and the second layer 320, signal patterns respectively corresponding to the first to fourth signal patterns 315-318 may be provided in association with the coupling patterns or may not be provided.

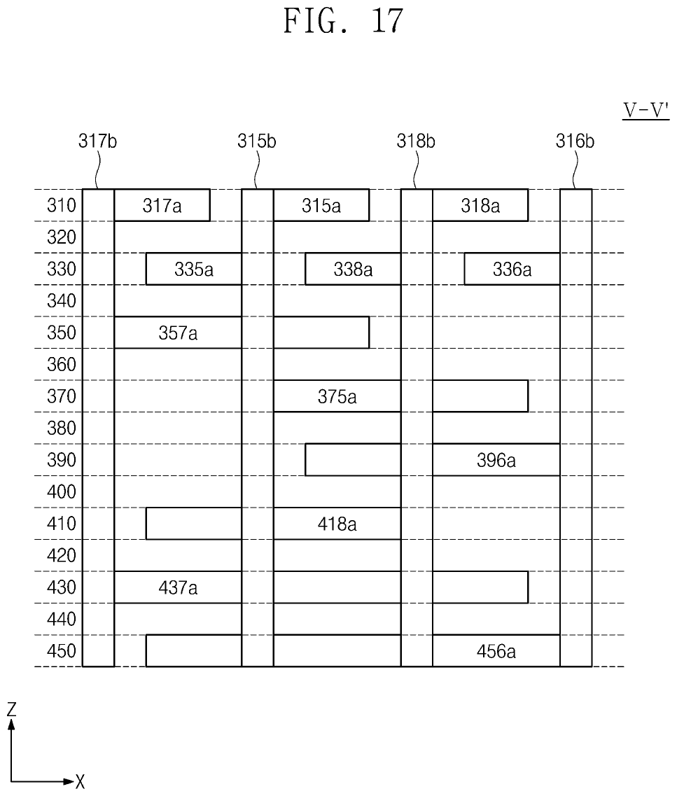

FIG. 17 is a sectional view taken along a line V-V′ of FIG. 16. Referring to FIGS. 16 and 17, the first to fourth connection vias 315b-318b may penetrate the first to fifteenth layers 310-450. The first to fourth signal patterns 315-318 connected to the first to fourth connection vias 315b-318b may be provided in the first layer 310, and may extend lengthwise in the second direction Y. In addition, the first coupling patterns 315a, 317a, and 318a, which are respectively extended from the first, third, and fourth signal patterns 315, 317, and 318, may be provided in the first layer 310 and may extend lengthwise in the first direction X.

Signal patterns connected to at least one of the first to fourth connection vias 315b-318b may be provided in the third layer 330. In addition, second coupling patterns 335a, 336a, and 338a, which are respectively extended from signal patterns corresponding to the first, second, and fourth connection vias 315b, 316b, and 318b, may be provided in the third layer 330.

Signal patterns connected to at least one of the second to fourth connection vias 316b-318b may be provided in the fifth layer 350. In addition, a third coupling pattern 357a, which is extended from a signal pattern corresponding to the third connection via 317b, may be provided in the fifth layer 350.

Signal patterns connected to at least one of the first to third connection vias 315b-317b may be provided in the seventh layer 370. In addition, a fourth coupling pattern 375a, which is extended from a signal pattern corresponding to the first connection via 315b, may be provided in the seventh layer 370.

Signal patterns connected to at least one of the first to third connection vias 315b-317b may be provided in the ninth layer 390. In addition, a fifth coupling pattern 396a, which is extended from a signal pattern corresponding to the second connection via 316b, may be provided in the ninth layer 390.

Signal patterns connected to at least one of the second to fourth connection vias 316b-318b may be provided in the eleventh layer 410. In addition, a sixth coupling pattern 418a, which is extended from a signal pattern corresponding to the fourth connection via 318b, may be provided in the eleventh layer 410.

Signal patterns connected to at least one of the second and third connection vias 316b and 317b may be provided in the thirteenth layer 430. In addition, a seventh coupling pattern 437a, which is extended from a signal pattern corresponding to the third connection via 317b, may be provided in the thirteenth layer 430.

Signal patterns connected to at least one of the second and third connection vias 316b and 317b may be provided in the fifteenth layer 450. In addition, an eighth coupling pattern 456a, which is extended from a signal pattern corresponding to the second connection via 316b, may be provided in the fifteenth layer 450.

The signal patterns connected to the first connection via 315b may be capacitively coupled with the signal patterns connected to the second connection via 316b, through at least the fourth coupling pattern 375a and the fifth coupling pattern 396a. The signal patterns connected to the first connection via 315b may be capacitively coupled with the signal patterns connected to the third connection via 317b, through at least the first coupling pattern 317a and the second coupling pattern 335a. The signal patterns connected to the first connection via 315b may be capacitively coupled with the signal patterns connected to the fourth connection via 318b, through at least the first coupling pattern 315a and the second coupling pattern 338a.

The signal patterns connected to the second connection via 316b may be capacitively coupled with the signal patterns connected to the first connection via 315b, through at least the fourth coupling pattern 375a and the fifth coupling pattern 396a. The signal patterns connected to the second connection via 316b may be capacitively coupled with the signal patterns connected to the third connection via 317b, through at least the seventh coupling pattern 437a and the eighth coupling pattern 456a. The signal patterns connected to the second connection via 316b may be capacitively coupled with the signal patterns connected to the fourth connection via 318b, through at least the first coupling pattern 318a and the second coupling pattern 336a.

The signal patterns connected to the third connection via 317b may be capacitively coupled with the signal patterns connected to the first connection via 315b, through at least the first coupling pattern 317a and the second coupling pattern 335a. The signal patterns connected to the third connection via 317b may be capacitively coupled with the signal patterns connected to the second connection via 316b, through at least the seventh coupling pattern 437a and the eighth coupling pattern 456a. The signal patterns connected to the third connection via 317b may be capacitively coupled with the signal patterns connected to the fourth connection via 318b, through at least the third coupling pattern 357a and the sixth coupling pattern 418a or through at least the sixth coupling pattern 418a and the seventh coupling pattern 437a.

The signal patterns connected to the fourth connection via 318b may be capacitively coupled with the signal patterns connected to the first connection via 315b, through at least the first coupling pattern 315a and the second coupling pattern 338a. The signal patterns connected to the fourth connection via 318b may be capacitively coupled with the signal patterns connected to the second connection via 316b, through at least the first coupling pattern 318a and the second coupling pattern 336a. The signal patterns connected to the fourth connection via 318b may be capacitively coupled with the signal patterns connected to the third connection via 317b, through at least the third coupling pattern 357a and the sixth coupling pattern 418a or through at least the sixth coupling pattern 418a and the seventh coupling pattern 437a.

As described above, a specific number of signal patterns may be capacitively coupled with each other completely, through coupling patterns extended from signal patterns.

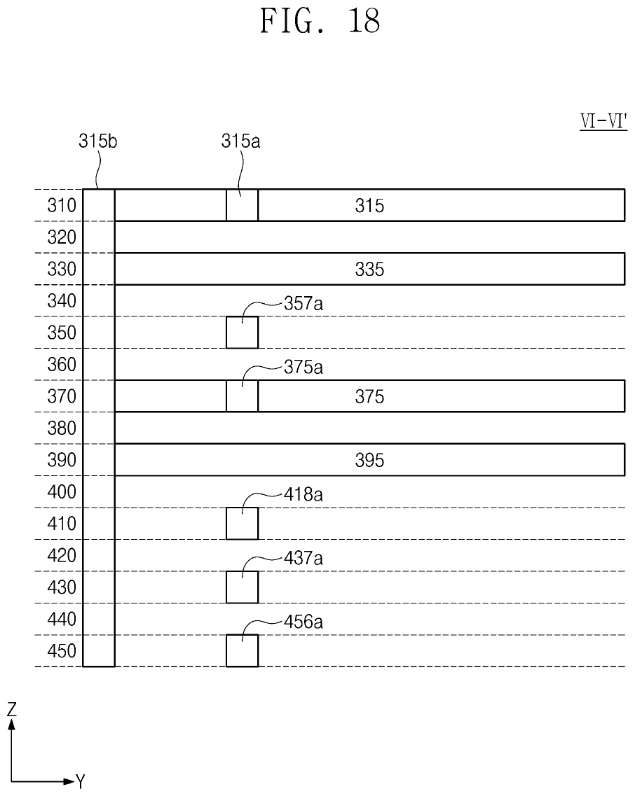

FIG. 18 is a sectional view taken along a line VI-VI′ of FIG. 16. Referring to FIGS. 16 to 18, the first signal pattern 315, which is connected to the first connection via 315b and the first coupling pattern 315a, may be provided in the first layer 310. A signal pattern 335 connected to the first connection via 315b may be provided in the third layer 330.

In the fifth layer 350, the third coupling pattern 357a may be provided to cross the first connection via 315b. To prevent an unintended connection with the third coupling pattern 357a, a signal pattern connected to the first connection via 315b may not be provided in the fifth layer 350.

A signal pattern 375, which is connected to the first connection via 315b and the fourth coupling pattern 375a, may be provided in the seventh layer 370. Since there is no coupling pattern crossing the first connection via 315b in the ninth layer 390, a signal pattern 395 connected to the first connection via 315b may be provided in the ninth layer 390.

In the eleventh layer 410, the sixth coupling pattern 418a may be provided to cross the first connection via 315b. To prevent an unintended connection with the sixth coupling pattern 418a, a signal pattern connected to the first connection via 315b may not be provided in the eleventh layer 410.

In the thirteenth layer 430, the seventh coupling pattern 437a may be provided to cross the first connection via 315b. To prevent an unintended connection with the seventh coupling pattern 437a, a signal pattern connected to the first connection via 315b may not be provided in the thirteenth layer 430.

In the fifteenth layer 450, the eighth coupling pattern 456a may be provided to cross the first connection via 315b. To prevent an unintended connection with the eighth coupling pattern 456a, a signal pattern connected to the first connection via 315b may not be provided in the fifteenth layer 450.

As described above, the presence or absence of signal patterns provided in each layer of the printed circuit board 201 may be determined in consideration of positions of coupling patterns constituting the signal coupler 121.

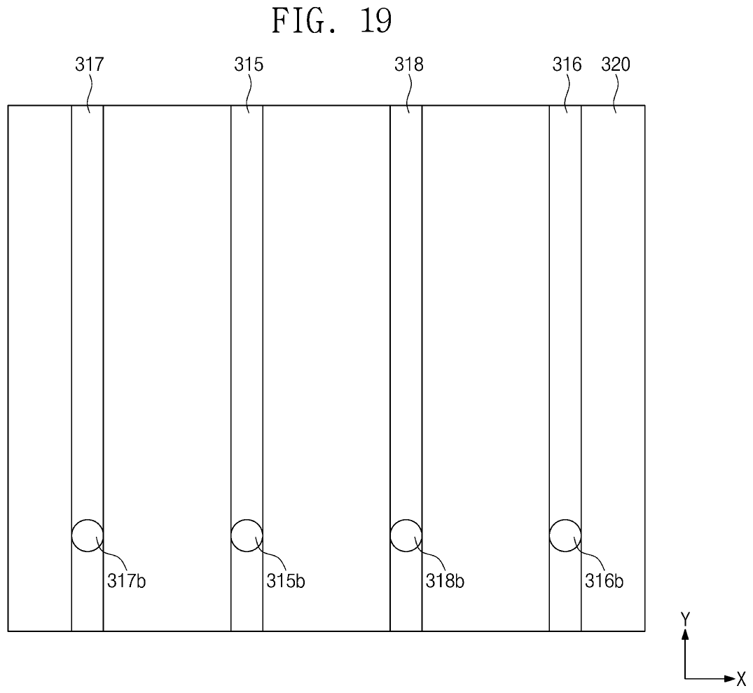

FIG. 19 illustrates an example of the first to fourth signal patterns 315-318, which are connected to first to fourth signal patterns extended from first to third vias of FIG. 7. For example, the first to fourth signal patterns 315-318 may extend from the first to fourth vias 311c-314c shown in FIG. 7 in the opposite direction of the second direction Y and may be connected to the first to fourth connection vias 315b-318b.

The first to fourth connection vias 315b-318b may penetrate the printed circuit board 201 and may be electrically connected to the first to fourth signal patterns 315-318, similar to the first to fourth vias 311c-314c. The first to fourth signal patterns 315-318 may form the first layer 310.

Coupling patterns for providing the capacitive coupling between the first to fourth signal patterns 315-318 may be provided in the underlying layers below the first layer 310 and the second layer 320. In certain embodiments, coupling patterns may extend from the first to fourth connection vias 315b-318b, unlike that described with reference to FIGS. 16 to 18.

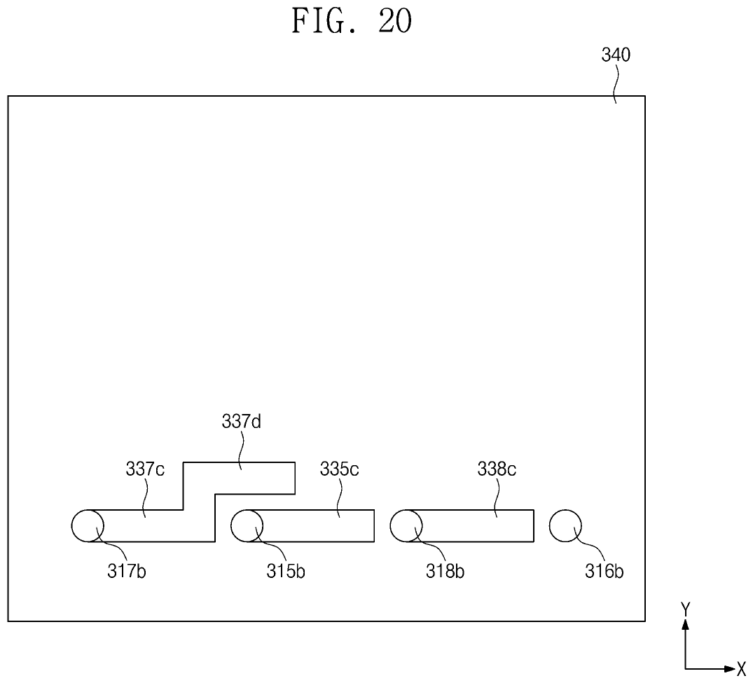

FIG. 20 illustrates an example of coupling patterns forming the fourth layer 340 and the third layer 330 on the fourth layer 340. Referring to FIG. 20, a first coupling pattern 335c may extend from the first connection via 315b in the first direction X.

Second coupling patterns 337c and 337d may extend from the third connection via 317b in the first direction X. The second coupling patterns 337c and 337d may include a first portion 337c and a second portion 337d, which is shifted from the first portion 337c in the second direction Y. The first portion 337c and the second portion 337d may be connected to one another with a bridging portion. A third coupling pattern 338c may extend from the fourth connection via 318b in the first direction X.

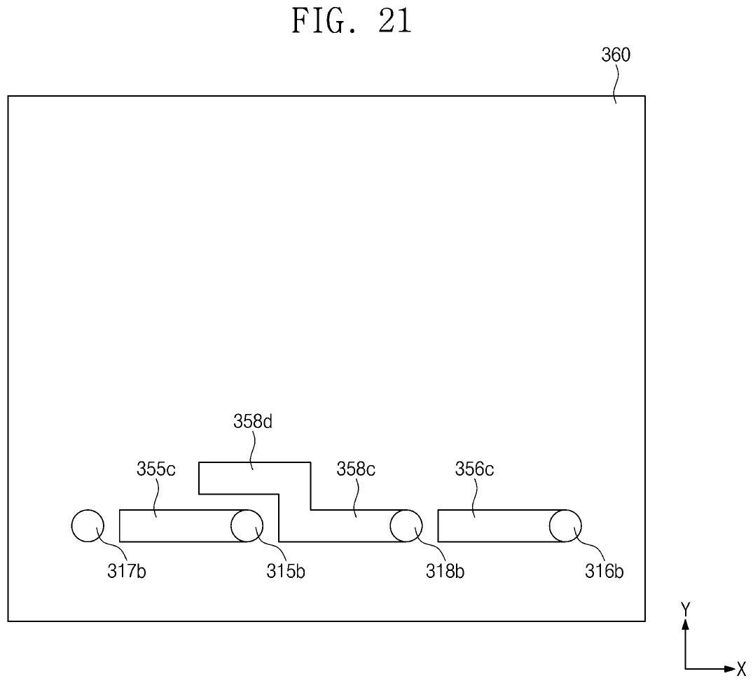

FIG. 21 illustrates an example of coupling patterns forming the sixth layer 360 and the fifth layer 350 on the sixth layer 360. Referring to FIG. 21, a fourth coupling pattern 355c may extend from the first connection via 315b in an opposite direction of the first direction X. A fifth coupling pattern 356c may extend from the second connection via 316b in the opposite direction of the first direction X.

Sixth coupling patterns 358c and 358d may extend from the fourth connection via 318b in the opposite direction of the first direction X. The sixth coupling patterns 358c and 358d may include a first portion 358c and a second portion 358d, which is shifted from the first portion 358c in the second direction Y. The first portion 358c and the second portion 358d may be connected to one another with a bridging portion.

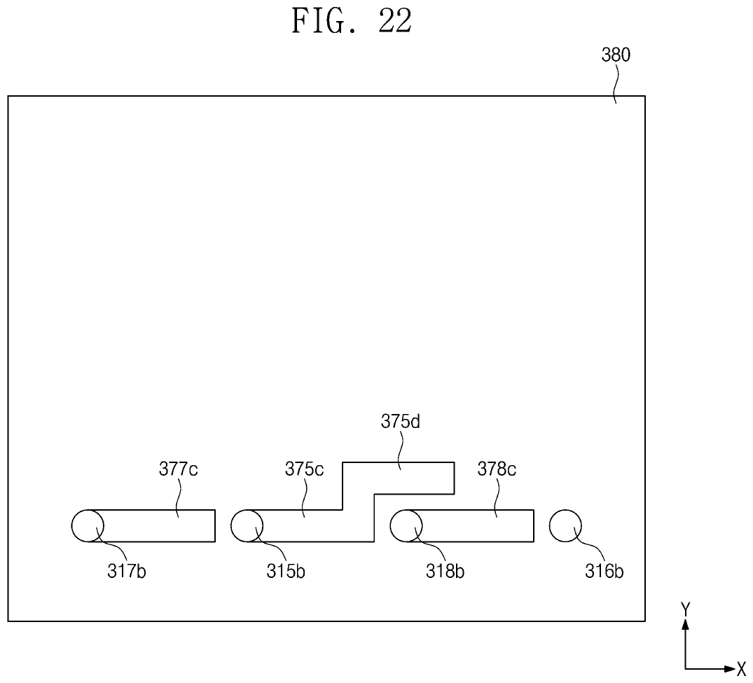

FIG. 22 illustrates an example of coupling patterns forming the eighth layer 380 and the seventh layer 370 on the eighth layer 380. Referring to FIG. 22, seventh coupling patterns 375c and 375d may extend from the first connection via 315b in the first direction X. The seventh coupling patterns 375c and 375d may include a first portion 375c and a second portion 375d, which is shifted from the first portion 375c in the second direction Y. The first portion 375c and the second portion 375d may be connected to one another with a bridging portion.

An eighth coupling pattern 377c may extend from the third connection via 317b in the first direction X. A ninth coupling pattern 378c may extend from the fourth connection via 318b in the first direction X.

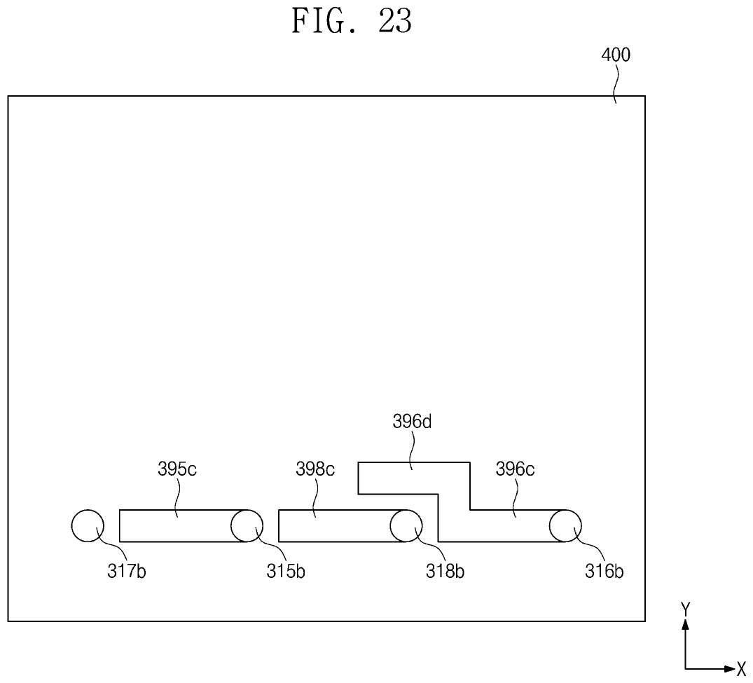

FIG. 23 illustrates an example of coupling patterns forming the tenth layer 400 and the ninth layer 390 on the tenth layer 400. Referring to FIG. 23, a tenth coupling pattern 395c may extend from the first connection via 315b in the opposite direction of the first direction X.

Eleventh coupling patterns 396c and 396d may extend from the second connection via 316b in the opposite direction of the first direction X. The eleventh coupling patterns 396c and 396d may include a first portion 396c and a second portion 396d, which is shifted from the first portion 396c in the second direction Y. The first portion 396c and the second portion 396d may be connected to one another with a bridging portion. A twelfth coupling pattern 398c may extend from the fourth connection via 318b in the opposite direction of the first direction X.

Referring to FIGS. 20 to 23, the first connection via 315b may be capacitively coupled with the second connection via 316b, through at least the second portion 375d of the seventh coupling patterns 375c and 375d and the second portion 396d of the eleventh coupling patterns 396c and 396d. The first connection via 315b may be capacitively coupled with the third connection via 317b, through at least the first portion 337c of the second coupling patterns 337c and 337d and the fourth coupling pattern 355c or through at least the eighth coupling pattern 377c and the tenth coupling pattern 395c. The first connection via 315b may be capacitively coupled with the fourth connection via 318b, through at least the first coupling pattern 335c and the first portion 358c of the sixth coupling patterns 358c and 358d or through at least the first portion 375c of the seventh coupling patterns 375c and 375d and the twelfth coupling pattern 398c.

The second connection via 316b may be capacitively coupled with the first connection via 315b through at least the second portion 375d of the seventh coupling patterns 375c and 375d and the second portion 396d of the eleventh coupling patterns 396c and 396d. The second connection via 316b may be capacitively coupled with the fourth connection via 318b through at least the third coupling pattern 338c and the fifth coupling pattern 356c or through at least the ninth coupling pattern 378c and the first portion 396c of the eleventh coupling patterns 396c and 396d.

The third connection via 317b may be capacitively coupled with the first connection via 315b through at least the first portion 337c of the second coupling patterns 337c and 337d and the fourth coupling pattern 355c or through at least the eighth coupling pattern 377c and the tenth coupling pattern 395c. The third connection via 317b may be capacitively coupled with the fourth connection via 318b through at least the second portion 337d of the second coupling patterns 337c and 337d and the second portion 358d of the sixth coupling patterns 358c and 358d.

The fourth connection via 318b may be capacitively coupled with the first connection via 315b through at least the first coupling pattern 335c and the first portion 358c of the sixth coupling patterns 358c and 358d or through at least the first portion 375c of the seventh coupling patterns 375c and 375d and the twelfth coupling pattern 398c. The fourth connection via 318b may be capacitively coupled with the second connection via 316b through at least the third coupling pattern 338c and the fifth coupling pattern 356c or through the ninth coupling pattern 378c and the first portion 396c of the eleventh coupling patterns 396c and 396d. The fourth connection via 318b may be capacitively coupled with the third connection via 317b through at least the second portion 337d of the second coupling patterns 337c and 337d and the second portion 358d of the sixth coupling patterns 358c and 358d.

As described above, simple coupling patterns extended from the first to fourth connection vias 315b-318b may be used to provide a complete capacitive coupling to connection vias having the proximity of second order, among the first to fourth connection vias 315b-318b.

Various coupling patterns forming the signal coupler 121 have been described in the afore-described embodiments. However, the shape, structure, and dimension of the coupling patterns are not limited to the afore-described embodiments. In the case where the coupling patterns are provided in a more complex manner or in a higher dimension, there may be a change in proximity of signal patterns or vias, to which the capacitive coupling is provided.

For example, capacitance between signal patterns or vias having the proximity of first order may be different from capacitance between signal patterns or vias having the proximity of second order. Similarly, capacitance between signal patterns or vias having the proximity of i-th order may be different from capacitance between signal patterns or vias having the proximity of j-th order, where i and j are positive integers different from each other.

As an example, as the proximity of signal patterns or vias provided in the printed circuit board 201 increases (or decreases), the capacitance between the signal patterns or vias may decrease (or increase). In certain embodiments, signal patterns or vias having the same proximity may have the same or similar capacitance.

The terms “first”, “second”, “third”, etc. may be used herein to describe various elements, which may be provided in the semiconductor memory module 200 and the printed circuit board 201 constituting the semiconductor memory module 200. These terms are only used to distinguish one element from another element, and the disclosure is not limited by these terms. For example, the terms “first”, “second”, “third”, etc. may not imply a specific order or numerical meaning. In addition, items described as “extending” in a particular direction from another refers to a lengthwise direction, such that the element has a length in the particular direction and a width perpendicular to that direction, where the length is greater than the width.

In the above-described embodiments, components according to example embodiments are referred to by using blocks. The blocks may be implemented with hardware, such as an integrated circuit (IC), an application specific IC (ASIC), a field programmable gate array (FPGA), and a complex programmable logic device (CPLD), software, such as firmware and applications driven in hardware devices, or combinations of hardware and software. Also, the blocks may include circuits that are implemented with semiconductor devices in an IC.

According to some example embodiments, a capacitive coupling may be provided between a specific number of signal lines. Thus, even when the arrangement or disposition of signal lines varies from module to module, it may be possible to prevent crosstalk between the signal lines in a semiconductor memory module or a semiconductor memory module board.

While example embodiments of the inventive concepts have been particularly shown and described, it will be understood by one of ordinary skill in the art that variations in form and detail may be made therein without departing from the spirit and scope of the attached claims.

What is claimed is:

1. A semiconductor memory module, comprising:
a printed circuit board; and
semiconductor memory packages provided on the printed circuit board,
wherein the printed circuit board comprises:
a connector provided at a side region of the printed circuit board and configured to be connected to an external device;
signal lines configured to connect the connector and the semiconductor memory packages to each other;
a first coupling element configured to provide a first capacitive coupling between first signal lines, which are closest to each other, among the signal lines;
a second coupling element configured to provide a second capacitive coupling between second signal lines, which are disposed adjacent to each other with one signal line interposed therebetween, among the signal lines; and
a third coupling element configured to provide a third capacitive coupling between third signal lines, which are disposed adjacent to each other with two signal lines interposed therebetween, among the signal lines.

2. The semiconductor memory module of claim 1, wherein, between the connector and the semiconductor memory packages, the signal lines, the first coupling element, the second coupling element, and the third coupling element are composed of only passive elements.

3. The semiconductor memory module of claim 1, wherein the semiconductor memory packages comprise at least one of a data buffer package, a memory package, and a register clock driver package.

4. The semiconductor memory module of claim 1, wherein the printed circuit board is implemented with two or more layers, and
the first coupling element comprises:
a first pattern connected to a first line of the first signal lines and extended from the first line of the first signal lines in a direction crossing the first line of the first signal lines, in a first layer of the two or more layers; and
a second pattern connected to a second line of the first signal lines and extended from the second line of the first signal lines in a direction crossing the second line of the first signal lines, in a second layer of the two or more layers, and
wherein the first pattern and the second pattern are partially overlapped with each other in a direction perpendicular to the two or more layers.

5. The semiconductor memory module of claim 1, wherein the printed circuit board is implemented with two or more layers, and
the second coupling element comprises:
a first pattern connected to a first line of the second signal lines and extended from the first line of the second signal lines in a direction crossing the first line of the second signal lines, in a first layer of the two or more layers; and
a second pattern connected to a second line of the second signal lines and extended from the second line of the second signal lines in a direction crossing the second line of the second signal lines, in a second layer of the two or more layers,
wherein the first pattern and the second pattern are partially overlapped with each other in a direction perpendicular to the two or more layers, and
wherein the one signal line interposed between the second signal lines is not provided in regions in which the first pattern and the second pattern are formed, respectively, in the first and second layers.

6. The semiconductor memory module of claim 1, wherein the printed circuit board is implemented with two or more layers, and
the third coupling element comprises:
a first pattern connected to a first line of the third signal lines and extended from the first line of the third signal lines in a direction crossing the first line of the third signal lines, in a first layer of the two or more layers; and
a second pattern connected to a second line of the third signal lines and extended from the second line of the third signal lines in a direction crossing the second line of the third signal lines, in a second layer of the two or more layers,
wherein the first pattern and the second pattern are partially overlapped with each other in a direction perpendicular to the two or more layers, and
wherein the two signal lines interposed between the third signal lines are not provided in regions in which the first pattern and the second pattern are formed, respectively, in the first and second layers.

7. The semiconductor memory module of claim 1,
wherein the printed circuit board is implemented with two or more layers,
wherein the first signal lines are disposed to be closest to each other among the signal lines, in at least one layer of the two or more layers,
wherein the second signal lines are spaced apart from each other with the one signal line interposed therebetween, in the at least one layer of the two or more layers, and
wherein the third signal lines are spaced apart from each other with the two signal lines interposed therebetween, in the at least one layer of the two or more layers.

8. The semiconductor memory module of claim 7, wherein the at least one layer comprises a layer in which all of the signal lines are provided.

9. The semiconductor memory module of claim 1,
wherein the printed circuit board is implemented with two or more layers and vias, and
wherein the vias are provided to penetrate the two or more layers and to form the signal lines, respectively.

10. The semiconductor memory module of claim 9, wherein the first coupling element comprises:
a first pattern extended from a first via of the vias in at least one first direction, in a first layer of the two or more layers; and
a second pattern extended from a second via of the vias in at least one second direction, in a second layer of the two or more layers,
wherein the first pattern and the second pattern are partially overlapped with each other in a direction perpendicular to the two or more layers.

11. The semiconductor memory module of claim 10, wherein the second coupling element comprises:
the first pattern; and
a third pattern extended from a third via of the vias in at least one third direction, in a third layer of the two or more layers,
wherein the first pattern and the third pattern are partially overlapped with each other in a direction perpendicular to the two or more layers, and
wherein the first pattern is shared with the first coupling element and the second coupling element.

12. The semiconductor memory module of claim 9, wherein the vias are disposed near regions to which solder balls of the semiconductor memory packages are attached.

13. The semiconductor memory module of claim 9, wherein the vias are arranged in a matrix shape.

14. The semiconductor memory module of claim 13,
wherein one of the vias, which is spaced apart from an edge of the matrix shape, comprises at least four coupling patterns respectively extended in at least four directions, and
wherein each of the at least four coupling patterns forms the first coupling element, the second coupling element, or the third coupling element, along with a pattern extended from at least one via adjacent thereto.

15. The semiconductor memory module of claim 13, wherein one of the vias, which is located at an edge of the matrix shape, comprises at least two coupling patterns respectively extended in at least two directions, and
wherein each of the at least two coupling patterns forms the first coupling element, the second coupling element, or the third coupling element, along with a pattern extended from at least one via adjacent thereto.

16. A semiconductor memory module board, comprising:
a connector configured to be connected to an external device;
attachment regions configured to allow semiconductor memory packages to be attached thereto;
signal lines configured to connect the connector and the attachment regions to each other;
a first coupling element configured to provide a first capacitive coupling between a first signal line and a second signal line, which is closest to the first signal line, among the signal lines;
a second coupling element configured to provide a second capacitive coupling between the first signal line and a third signal line, which is spaced adjacent to the first signal line with the second signal line interposed therebetween, among the signal lines; and
a third coupling element configured to provide a third capacitive coupling between the first signal line and a fourth signal line, which is spaced adjacent to the first signal line with the second and third signal lines interposed therebetween, among the signal lines.

17. The semiconductor memory module board of claim 16, further comprising:
a fourth coupling element configured to provide a fourth capacitive coupling between the second signal line and the third signal line; and
a fifth coupling element configured to provide a fifth capacitive coupling between the third signal line and the fourth signal line.

18. The semiconductor memory module board of claim 16, further comprising:
a fourth coupling element configured to provide a fourth capacitive coupling between the fourth signal line and a fifth signal line, which is closest to the fourth signal line, among the signal lines;
a fifth coupling element configured to provide a fifth capacitive coupling between the second signal line and the fifth signal line; and
a sixth coupling element configured to provide a sixth capacitive coupling between the third signal line and the fifth signal line.

19. A semiconductor memory module, comprising:
a printed circuit board; and
semiconductor memory packages provided on the printed circuit board,
wherein the printed circuit board comprises:
a connector provided at a side region of the printed circuit board and configured to be connected to an external device;
n signal lines configured to connect the connector and the semiconductor memory packages to each other; and
coupling elements, each of which provides a capacitive coupling to k-th to (k+i)-th signal lines, among the signal lines, where k and i are positive integers smaller than n, and
wherein the k is an integer varying in a range from 1 to n−i.

20. The semiconductor memory module of claim 19, wherein the coupling elements comprise capacitors, which are formed by coupling patterns extended from the signal lines.
